(19) United States
(12) Patent Application Publication
(10) Pub. No.: US 2026/0110110 A1
(43) Pub. Date: Apr. 23, 2026

(54) POLYCRYSTALLINE DIAMOND FILMS AND RELATED METHODS

(71) Applicant: ENTEGRIS, INC., Billerica, MA (US)

(72) Inventors: Rajiv K. Singh, Newberry, FL (US); Sunny De, Oviedo, FL (US); Aditya Dilip Verma, San Jose, CA (US); Akshay Rajopadhye, Fremont, CA (US)

(21) Appl. No.: 19/364,278

(22) Filed: Oct. 21, 2025

Related U.S. Application Data
(60) Provisional application No. 63/711,115, filed on Oct. 23, 2024.

(51) Int. Cl. C30B 28/14; C30B 29/04

(52) U.S. Cl. CPC C30B 28/14; C30B 29/04

(57) ABSTRACT

Polycrystalline diamond films and related methods for polished coated substrates are described herein. The article comprises a polycrystalline substrate. The article comprises a polycrystalline diamond film located on the polycrystalline substrate. The polycrystalline diamond film has an average grain size that is smaller than an average grain size of the polycrystalline substrate. The polycrystalline diamond film has an average surface roughness Rₐ of 50 nm or less as measured by atomic force microscopy (AFM).

### FIELD

The present disclosure relates to polycrystalline diamond films and related methods for polished coated substrates.

### BACKGROUND

Chemical mechanical polishing is a process of smoothing surfaces with the combination of chemical and mechanical forces.

### SUMMARY

Some embodiments relate to an article. In some embodiments, the article comprises a polycrystalline substrate. In some embodiments, the article comprises a polycrystalline diamond film located on the polycrystalline substrate. In some embodiments, the polycrystalline diamond film has an average grain size that is smaller than an average grain size of the polycrystalline substrate. In some embodiments, the polycrystalline diamond film has an average surface roughness Rₐ of 50 nm or less as measured by atomic force microscopy (AFM).

Some embodiments relate to a method. In some embodiments, the method comprises obtaining a polycrystalline diamond. In some embodiments, the method comprises heating the polycrystalline diamond to obtain a vapor. In some embodiments, the method comprises contacting a polycrystalline substrate with the vapor to form a polycrystalline diamond film on the polycrystalline substrate. In some embodiments, the polycrystalline diamond film has an average grain size that is smaller than an average grain size of the polycrystalline substrate. In some embodiments, the polycrystalline diamond film has an average surface roughness Rₐ of 50 nm or less as measured by atomic force microscopy (AFM).

Some embodiments relate to a method. In some embodiments, the method comprises obtaining an article. In some embodiments, the article comprises a coated substrate. In some embodiments, the coated substrate comprises a polycrystalline substrate. In some embodiments, the coated substrate comprises a polycrystalline diamond film located on the polycrystalline substrate. In some embodiments, the polycrystalline diamond film has an average grain size that is smaller than an average grain size of the polycrystalline substrate. In some embodiments, the polycrystalline diamond film has an average surface roughness Rₐ of 50 nm or less as measured by atomic force microscopy (AFM). In some embodiments, the method comprises polishing the coated substrate, while a composition is located between the coated substrate and a polishing pad, to obtain a polished coated substrate. In some embodiments, the polished coated substrate has an average surface roughness Rₐ of less than 10 nm as measured by AFM.

### DRAWINGS

FIG. 1 is a flowchart of a method for forming a polycrystalline diamond film on a polycrystalline substrate, according to some embodiments.

FIG. 2 is a flowchart of a method for obtaining a polished coated substrate, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “contacting” refers to bringing two or more components into immediate or close proximity, or into direct contact.

Power devices such as dielectric films in semiconductor integrated circuits, optoelectronic devices such as light emitting devices (LEDs) and lasers, microelectromechanical systems (MEMS) based devices, and bio-medical systems, undergo chemical mechanical planarization (CMP) polishing to achieve smooth surfaces when polishing a polycrystalline substrate used to build the power device. CMP polishing may not meet surface finish requirements due to the large grain size, such as diamond, found in the polycrystalline substrate. Embodiments provided herein overcome at least these challenges associated with the reduction of surface roughness. Obtaining smooth surfaces may be achieved with a reduction of surface roughness of a polycrystalline substrate.

Some embodiments relate to an article.

In some embodiments, the article comprises a polycrystalline substrate. In some embodiments, the polycrystalline substrate comprises at least one of a polycrystalline diamond, a diamond film stack, or any combination thereof. In some embodiments, the polycrystalline substrate comprises a polycrystalline diamond. In some embodiments, the polycrystalline substrate comprises a diamond film stack. In some embodiments, the diamond film stack comprises a diamond layer located on a substrate. In some embodiments, the substrate comprises a single-crystalline material. In some embodiments, the single-crystalline material comprises at least one of a silicon, a nitride, a carbide, a metal oxide, a metal, or any combination thereof.

In some embodiments, the single-crystalline material comprises at least one of at least one of a silicon, a silicon nitride, a silicon oxynitride, a silicon oxide, a silicon dioxide, a silicon carbide, a silicon carbonitride, a silicon oxycarbonitride, a carbon-doped silicon nitride, a carbon-doped silicon oxide, a carbon-doped silicon oxynitride, or any combination thereof.

In some embodiments, the metal oxide comprises at least one of an aluminum oxide, a silicon oxide, an yttrium oxide, a magnesium oxide, a calcium oxide, a zirconium oxide, a hafnium oxide, a boron oxide, or any combination thereof.

In some embodiments, the metal comprises at least one of an alkali metal, an alkaline earth metal, a transition metal, a post-transition metal, or any combination thereof. In some embodiments, the metal comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof.

In some embodiments, the polycrystalline substrate comprises a polycrystalline silicon carbide.

In some embodiments, the polycrystalline substrate has an average grain size of 4 μm to 100 μm, or any range or subrange between 4 μm to 100 μm. For example, in some embodiments, the polycrystalline substrate has an average grain size of 10 μm to 90 μm, 20 μm to 80 μm, 30 μm to 70 μm, or 40 μm to 60 μm. In some embodiments, the polycrystalline substrate has an average grain size of 10 μm to 100 μm, 20 μm to 100 μm, 30 μm to 100 μm, 40 μm to 100 μm, 50 μm to 100 μm, 60 μm to 100 μm, 70 μm to 100 μm, 80 μm to 100 μm, or 90 μm to 100 μm. In some embodiments, the polycrystalline substrate has an average grain size of 4 μm to 90 μm, 4 μm to 80 μm, 4 μm to 70 μm, 4 μm to 60 μm, 4 μm to 50 μm, 4 μm to 40 μm, 4 μm to 30 μm, 4 μm to 20 μm, 4 μm to 10 μm, or 4 μm to 5 μm.

In some embodiments, the article comprises a polycrystalline diamond film located on the polycrystalline substrate. In some embodiments, the polycrystalline diamond film is attached to the polycrystalline substrate. In some embodiments, the polycrystalline diamond film is adhered to the polycrystalline substrate. In some embodiments, the polycrystalline diamond film directly contacts the polycrystalline substrate. In some embodiments, the polycrystalline diamond film is deposited on to the polycrystalline substrate. In some embodiments, the polycrystalline diamond film is anchored to the polycrystalline substrate. In some embodiments, the polycrystalline diamond film is bonded to the polycrystalline substrate. In some embodiments, the polycrystalline diamond film is grown on the polycrystalline substrate.

In some embodiments, the polycrystalline diamond film comprises a layer of diamonds. In some embodiments, the polycrystalline diamond film comprises a plurality of diamond particles. In some embodiments, the plurality of diamond particles has an average particle size of less than 0.1 μm. For example, in some embodiments, the plurality of diamond particles has an average particle size of 0.01 μm to 0.1 μm, or any range or subrange between 0.01 μm and 0.1 μm. In some embodiments, the plurality of diamond particles has an average particle size of 0.02 μm to 0.09 μm, 0.03 μm to 0.08 μm, 0.04 μm to 0.07 μm, or 0.05 μm to 0.06 μm. In some embodiments, the plurality of diamond particles has an average particle size of 0.02 μm to 0.1 μm, 0.03 μm to 0.1 μm, 0.04 μm to 0.1 μm, 0.05 μm to 0.1 μm, 0.1 μm, 0.06 μm to 0.1 μm, 0.07 μm to 0.1 μm, 0.08 μm to 0.1 μm, or 0.09 μm to 0.1 μm. In some embodiments, the plurality of diamond particles has an average particle size of 0.01 μm to 0.09 μm, 0.01 μm to 0.08 μm, 0.01 μm to 0.07 μm, 0.01 μm to 0.06 μm, 0.01 μm to 0.05 μm, 0.01 μm to 0.04 μm, 0.01 μm to 0.02 μm, or 0.01 μm to 0.02 μm.

In some embodiments, the polycrystalline diamond film is obtained by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the polycrystalline diamond film has an average grain size that is smaller than an average grain size of the polycrystalline substrate.

In some embodiments, the polycrystalline diamond film has an average grain size of less than 0.1 μm. For example, in some embodiments, the polycrystalline diamond film has an average grain size of 0.01 μm to 0.1 μm, or any range or subrange between 0.01 μm and 0.1 μm. In some embodiments, the polycrystalline diamond film has an average grain size of 0.02 μm to 0.09 μm, 0.03 μm to 0.08 μm, 0.04 μm to 0.07 μm, or 0.05 μm to 0.06 μm. In some embodiments, the polycrystalline diamond film has an average grain size of 0.02 μm to 0.1 μm, 0.03 μm to 0.1 μm, 0.04 μm to 0.1 μm, 0.05 μm to 0.1 μm, 0.1 μm, 0.06 μm to 0.1 μm, 0.07 μm to 0.1 μm, 0.08 μm to 0.1 μm, or 0.09 μm to 0.1 μm. In some embodiments, the polycrystalline diamond film has an average grain size of 0.01 μm to 0.09 μm, 0.01 μm to 0.08 μm, 0.01 μm to 0.07 μm, 0.01 μm to 0.06 μm, 0.01 μm to 0.05 μm, 0.01 μm to 0.04 μm, 0.01 μm to 0.02 μm, or 0.01 μm to 0.02 μm.

In some embodiments, the polycrystalline diamond film has an average grain size of 0.1 μm to 10 μm, or any combination thereof. For example, in some embodiments, the polycrystalline diamond film has an average grain size of 0.5 μm to 9 μm, 1 μm to 8 μm, 2 μm to 7 μm, 3 μm to 6 μm, or 4 μm to 5 μm. In some embodiments, the polycrystalline diamond film has an average grain size of 0.1 μm to 9 μm, 0.1 μm to 8 μm, 0.1 μm to 7 μm, 0.1 μm to 6 μm, 0.1 μm to 5 μm, 0.1 μm to 4 μm, 0.1 μm to 3 μm, 0.1 μm to 2 μm, 0.1 μm to 1 μm, or 0.1 μm to 0.5 μm. In some embodiments, the polycrystalline diamond film has an average grain size of 0.5 μm to 10 μm, 1 μm to 10 μm, 2 μm to 10 μm, 3 μm to 10 μm, 4 μm to 10 μm, 5 μm to 10 μm, 6 μm to 10 μm, 7 μm to 10 μm, 8 μm to 10 μm, or 9 μm to 10 μm.

In some embodiments, the polycrystalline diamond film has an average grain size 2 times to 1000 times smaller than an average grain size of the polycrystalline substrate. For example, in some embodiments, the polycrystalline diamond film has an average grain size 10 times to 900 times, 50 times to 800 times, 100 times to 700 times, 200 times to 600 times, or 300 times to 500 times smaller than an average grain size of the polycrystalline substrate. In some embodiments, the polycrystalline diamond film has an average grain size 10 times to 1000 times, 50 times to 1000 times, 100 times to 1000 times, 200 times to 1000 times, 300 times to 1000 times, 400 times to 1000 times, 500 times to 1000 times, 600 times to 1000 times, 700 times to 1000 times, 800 times to 1000 times, or 900 times to 1000 times smaller than an average grain size of the polycrystalline substrate

In some embodiments, the polycrystalline diamond film has an average grain size 10 times to 100 times smaller than an average grain size of the polycrystalline substrate. For example, in some embodiments, the polycrystalline diamond film has an average grain size 20 times to 90 times, 30 times to 80 times, 40 times to 70 times, or 50 times to 60 times smaller than an average grain size of the polycrystalline substrate. In some embodiments, the polycrystalline diamond film has an average grain size 10 times to 90 times, 10 times to 80 times, 10 times to 70 times, 10 times to 60 times, 10 times to 50 times, 10 times to 40 times, 10 times to 30 times, or 10 times to 20 times smaller than an average grain size of the polycrystalline substrate. In some embodiments, the polycrystalline diamond film has an average grain size 20 times to 100 times, 30 times to 100 times, 40 times to 100 times, 50 times to 100 times, 60 times to 100 times, 70 times to 100 times, 80 times to 100 times, or 90 times to 100 times smaller than an average grain size of the polycrystalline substrate.

In some embodiments, the polycrystalline diamond film has an average surface roughness (Rₐ) of 50 nm or less as measured by atomic force microscopy (AFM). For example, in some embodiments, the polycrystalline diamond film has a Rₐ of 0.1 nm to 50 nm, or any range or subrange between 0.1 nm to 50 nm as measured by AFM. In some embodiments, the polycrystalline diamond film has a Rₐ of 1 nm to 45 nm, 5 nm to 40 nm, 10 nm to 35 nm, 15 nm to 30 nm, or 20 nm to 25 nm as measured by AFM. In some embodiments, the polycrystalline diamond film has a Rₐ of 0.1 nm to 45 nm, 0.1 nm to 40 nm, 0.1 nm to 35 nm, 0.1 nm to 30 nm, 0.1 nm to 25 nm, 0.1 nm to 20 nm, 0.1 nm to 15 nm, 0.1 nm to 10 nm, or 0.1 nm to 5 nm as measured by AFM. In some embodiments, the polycrystalline diamond film has a Rₐ of 1 nm to 50 nm, 5 nm to 50 nm, 10 nm to 50 nm, 15 nm to 50 nm, 20 nm to 50 nm, 25 nm to 50 nm, 30 nm to 50 nm, 35 nm to 50 nm, 40 nm to 50 nm as measured by AFM.

In some embodiments, the polycrystalline diamond film has an Rₐ of 10 nm or less as measured by AFM. For example, in some embodiments, the polycrystalline diamond film has a Rₐ of 0.1 nm to 10 nm, or any range or subrange between 0.1 nm to 10 nm as measured by AFM. In some embodiments, the polycrystalline diamond film has a Rₐ of 1 nm to 9 nm, 2 nm to 8 nm, 3 nm to 7 nm, or 4 nm to 6 nm as measured by AFM. In some embodiments, the polycrystalline diamond film has a Rₐ of 0.1 nm to 9 nm, 0.1 nm to 8 nm, 0.1 nm to 7 nm, 0.1 nm to 6 nm, 0.1 nm to 5 nm, 0.1 nm to 4 nm, 0.1 nm to 3 nm, 0.1 nm to 2 nm, or 0.1 nm to 1 nm as measured by AFM. In some embodiments, the polycrystalline diamond film has a Rₐ of 1 nm to 9 nm, 1 nm to 8 nm, 1 nm to 7 nm, 1 nm to 6 nm, 1 nm to 5 nm, 1 nm to 4 nm, 1 nm to 3 nm, or 1 nm to 2 nm as measured by AFM.

In some embodiments, the polycrystalline diamond film has an Rₐ of less than 1 nm as measured by AFM. In some embodiments, the polycrystalline diamond film has an Rₐ of 0.2 nm to 1 nm as measured by AFM. For example, in some embodiments, the polycrystalline diamond film has a Rₐ of 0.2 nm to 1 nm, or any range or subrange between 0.2 nm to 1 nm as measured by AFM. In some embodiments, the polycrystalline diamond film has a Rₐ of 0.2 nm to 0.9 nm, 0.3 nm to 0.8 nm, 0.4 nm to 0.7 nm, or 0.5 nm to 0.6 nm as measured by AFM. In some embodiments, the polycrystalline diamond film has a Rₐ of 0.3 nm to 1 nm, 0.4 nm to 1 nm, 0.5 nm to 1 nm, 0.6 nm to 1 nm, 0.7 nm to 1 nm, 0.8 nm to 1 nm, or 0.9 nm to 1 nm as measured by AFM. In some embodiments, the polycrystalline diamond film has a Rₐ of 0.2 nm to 0.8 nm, 0.2 nm to 0.7 nm, 0.2 nm to 0.6 nm, 0.2 nm to 0.5 nm, 0.2 nm to 0.4 nm, or 0.2 nm to 0.3 nm as measured by AFM.

In some embodiments, the polycrystalline diamond film has a root mean square surface roughness R_{q} of less than 1 nm as measured by AFM. In some embodiments, the polycrystalline diamond film has an R_{q} of 0.1 nm to 1 nm as measured by AFM. For example, in some embodiments, the polycrystalline diamond film has a R_{q} of 0.1 nm to 1 nm, or any range or subrange between 0.1 nm to 1 nm as measured by AFM. In some embodiments, the polycrystalline diamond film has a R_{q} of 0.1 nm to 0.9 nm, 0.2 nm to 0.8 nm, 0.3 nm to 0.7 nm, or 0.4 nm to 0.6 nm as measured by AFM. In some embodiments, the polycrystalline diamond film has a R_{q} of 0.2 nm to 1 nm, 0.3 nm to 1 nm, 0.4 nm to 1 nm, 0.5 nm to 1 nm, 0.6 nm to 1 nm, 0.7 nm to 1 nm, 0.8 nm to 1 nm, or 0.9 nm to 1 nm as measured by AFM. In some embodiments, the polycrystalline diamond film has a R_{q} of 0.1 nm to 0.9 nm, 0.1 nm to 0.8 nm, 0.1 nm to 0.7 nm, 0.1 nm to 0.6 nm, 0.1 nm to 0.5 nm, 0.1 nm to 0.4 nm, 0.1 nm to 0.3 nm, or 0.1 nm to 0.3 nm as measured by AFM.

In some embodiments, the polycrystalline diamond film has a thickness that is less than a thickness of the polycrystalline substrate.

In some embodiments, the polycrystalline diamond film has a thickness of 1 μm to 100 μm, or any range or subrange between 1 μm to 100 μm. For example, in some embodiments, the polycrystalline diamond film has a thickness of 5 μm to 95 μm, 10 μm to 90 μm, 15 μm to 85 μm, 20 μm to 80 μm, 25 μm to 75 μm, 30 μm to 70 μm, 35 μm to 65 μm, 40 μm to 60 μm, or 45 μm to 55 μm. In some embodiments, the polycrystalline diamond film has a thickness of 10 μm to 100 μm, 20 μm to 100 μm, 30 μm to 100 μm, 40 μm to 100 μm, 50 μm to 100 μm, 60 μm to 100 μm, 70 μm to 100 μm, 80 μm to 100 μm, or 90 μm to 100 μm.

In some embodiments, the polycrystalline diamond film has a thickness of 1 μm to 10 μm, or any range or subrange between 1 μm to 10 μm. For example, in some embodiments, the polycrystalline diamond film has a thickness of 2 μm to 9 μm, 3 μm to 8 μm, 4 μm to 7 μm, or 5 μm to 6 μm. In some embodiments, the polycrystalline diamond film has a thickness of 1 μm to 9 μm, 1 μm to 8 μm, 1 μm to 7 μm, 1 μm to 6 μm, 1 μm to 5 μm, 1 μm to 4 μm, 1 μm to 3 μm, or 1 μm to 2 μm.

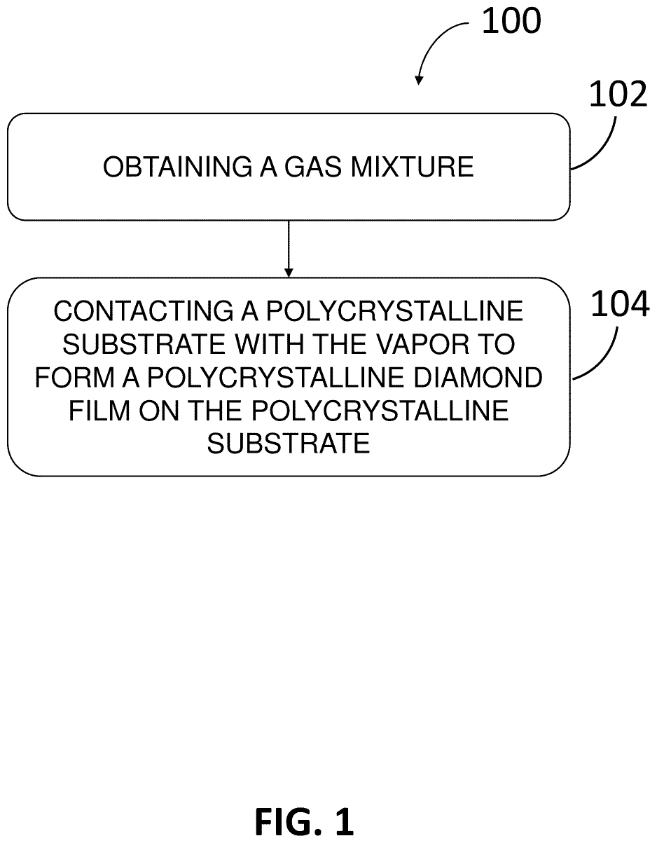

FIG. 1 is a flowchart of a method for forming a polycrystalline diamond film on a polycrystalline substrate, according to some embodiments. As shown in FIG. 1, the method for forming a polycrystalline diamond film on a polycrystalline substrate may comprise one or more of the following steps: obtaining a polycrystalline diamond, heating the polycrystalline diamond to obtain a vapor, and contacting a polycrystalline substrate with the vapor to form a polycrystalline diamond film on the polycrystalline substrate.

At step 102, in some embodiments, the method comprises obtaining a gas mixture. In some embodiments, the gas mixture comprises a hydrogen and a hydrocarbon. In some embodiments, the hydrocarbon comprises at least one of a methane, an ethane, a propane, a butane, a pentane, or any combination thereof. In some embodiments, the hydrocarbon comprises a methane. In some embodiments, the hydrocarbon comprises an ethane. In some embodiments, the hydrocarbon comprises a propane. In some embodiments, the hydrocarbon comprises a butane. In some embodiments, the hydrocarbon comprises a pentane.

In some embodiments, the feed gas comprises 0.01% to 10% by weight of the hydrocarbon based on a total weight of the feed gas, or any range or subrange between 0.01% and 10%. For example, in some embodiments, the feed gas comprises 0.1% to 9%, 0.5% to 8%, 1% to 7%, 2% to 6%, or 3% to 5% by weight of the hydrocarbon based on a total weight of the feed gas. In some embodiments, the feed gas comprises 0.1% to 10%, 0.5% to 10%, 1% to 10%, 2% to 10%, 3% to 10%, 4% to 10%, 5% to 10%, 6% to 10%, 7% to 10%, 8% to 10%, 9% to 10% by weight of the hydrocarbon based on a total weight of the feed gas. In some embodiments, the feed gas comprises 0.01% to 9%, 0.01% to 8%, 0.01% to 7%, 0.01% to 6%, 0.01% to 5%, 0.01% to 4%, 0.01% to 3%, 0.01% to 2%, 0.01% to 1%, 0.01% to 0.5%, or 0.01% to 0.1% by weight of the hydrocarbon based on a total weight of the feed gas.

At step 104, in some embodiments, the method comprises contacting a polycrystalline substrate with the gas mixture to form a polycrystalline diamond film on the polycrystalline substrate.

In some embodiments, the contacting comprises bringing the gas mixture and the polycrystalline substrate into immediate or close proximity. In some embodiments, the contacting comprises bringing the gas mixture and polycrystalline substrate into direct physical contact. In some embodiments, the contacting comprises adding the polycrystalline substrate to the gas mixture, or vice versa. In some embodiments, the contacting proceeds for a duration of one second to 5 hours, or any range or subrange between one second and 5 hours. In some embodiments, the contacting comprises exposing the polycrystalline substrate to the gas mixture. In some embodiments, the contacting comprises introducing, supplying, pumping, drawing (e.g., via vacuum), injecting, flowing, or otherwise providing the gas mixture such that the vapor and the polycrystalline substrate are contacted.

In some embodiments, the contacting comprises heating a container comprising the gas mixture. In some embodiments, the contacting comprises heating the gas mixture in a deposition chamber in which the vapor deposition process is performed. In some embodiments, the contacting comprises operating a vapor delivery system comprising the gas mixture. In some embodiments, the contacting comprises heating to a temperature sufficient to vaporize the gas mixture to form the vapor.

In some embodiments, the heating is conducted at a temperature of 600° C. to 1200° C., or any range or subrange between 600° C. to 1200° C. For example, in some embodiments, the heating is conducted at a temperature of 650° C. to 1150° C., 700° C. to 1100° C., 750° C. to 1050° C., 800° C. to 1000° C., or 850° C. to 950° C. In some embodiments, the heating is conducted at a temperature of 700° C. to 1200° C., 800° C. to 1200° C., 900° C. to 1200° C., 1000° C. to 1200° C., or 1100° C. to 1200° C. In some embodiments, the heating is conducted at a temperature of 600° C. to 1100° C., 600° C. to 1000° C., 600° C. to 900° C., 600° C. to 800° C., 600° C. to 700° C.

In some embodiments, the heating is conducted at a pressure less than 100 Torr. For example, the heating is conducted at a pressure of 20 Torr to 30 Torr, or any range or subrange between 20 Torr and 30 Torr. For example, in some embodiments, the heating is conducted at a pressure of 21 Torr to 29 Torr, 22 Torr to 28 Torr, 23 Torr to 27 Torr, or 24 Torr to 26 Torr. In some embodiments, the heating is conducted at a pressure of 21 Torr to 30 Torr, 22 Torr to 30 Torr, 23 Torr to 30 Torr, 24 Torr to 30 Torr, 25 Torr to 30 Torr, 26 Torr to 30 Torr, 27 Torr to 30 Torr, 28 Torr to 30 Torr, or 29 Torr to 30 Torr.

In some embodiments, the heating is conducted at a pressure of 1 Torr to 100 Torr, or any range or subrange between 1 Torr and 100 Torr. In some embodiments, the heating is conducted at a pressure of 10 Torr to 90 Torr, 20 Torr to 80 Torr, 30 Torr to 70 Torr, or 40 Torr to 60 Torr. In some embodiments, the heating is conducted at a pressure of 10 Torr to 100 Torr, 20 Torr to 100 Torr, 30 Torr to 100 Torr, 40 Torr to 100 Torr, 50 Torr to 100 Torr, 60 Torr to 100 Torr, 70 Torr to 100 Torr, 80 Torr to 100 Torr, or 90 Torr to 100 Torr. In some embodiments, the heating is conducted at a pressure of 1 Torr to 90 Torr, 1 Torr to 80 Torr, 1 Torr to 70 Torr, 1 Torr to 60 Torr, 1 Torr to 50 Torr, 1 Torr to 40 Torr, 1 Torr to 30 Torr, 1 Torr to 20 Torr, 1 Torr to 10 Torr, or 1 Torr to 5 Torr.

In some embodiments, the polycrystalline diamond film has an average grain size that is smaller than an average grain size of the polycrystalline substrate, as described herein.

In some embodiments, the polycrystalline diamond film has an average surface roughness (Rₐ) of 50 nm or less as measured by atomic force microscopy (AFM). For example, in some embodiments, the polycrystalline diamond film has a Rₐ of 0.1 nm to 50 nm, or any range or subrange between 0.1 nm to 50 nm as measured by AFM. In some embodiments, the polycrystalline diamond film has a Rₐ of 1 nm to 45 nm, 5 nm to 40 nm, 10 nm to 35 nm, 15 nm to 30 nm, or 20 nm to 25 nm as measured by AFM. In some embodiments, the polycrystalline diamond film has a Rₐ of 0.1 nm to 45 nm, 0.1 nm to 40 nm, 0.1 nm to 35 nm, 0.1 nm to 30 nm, 0.1 nm to 25 nm, 0.1 nm to 20 nm, 0.1 nm to 15 nm, 0.1 nm to 10 nm, or 0.1 nm to 5 nm as measured by AFM. In some embodiments, the polycrystalline diamond film has a Rₐ of 1 nm to 50 nm, 5 nm to 50 nm, 10 nm to 50 nm, 15 nm to 50 nm, 20 nm to 50 nm, 25 nm to 50 nm, 30 nm to 50 nm, 35 nm to 50 nm, 40 nm to 50 nm as measured by AFM.

In some embodiments, the polycrystalline diamond film has an average surface roughness Rₐ of 10 nm or less as measured by AFM. In some embodiments, the polycrystalline diamond film has an Rₐ of 0.1 nm to 1 nm as measured by AFM. For example, in some embodiments, the polycrystalline diamond film has a Rₐ of 0.1 nm to 1 nm, or any range or subrange between 0.1 nm to 1 nm as measured by AFM. In some embodiments, the polycrystalline diamond film has a Rₐ of 0.1 nm to 0.9 nm, 0.2 nm to 0.8 nm, 0.3 nm to 0.7 nm, or 0.4 nm to 0.6 nm as measured by AFM. In some embodiments, the polycrystalline diamond film has a Rₐ of 0.2 nm to 1 nm, 0.3 nm to 1 nm, 0.4 nm to 1 nm, 0.5 nm to 1 nm, 0.6 nm to 1 nm, 0.7 nm to 1 nm, 0.8 nm to 1 nm, or 0.9 nm to 1 nm as measured by AFM. In some embodiments, the polycrystalline diamond film has a Rₐ of 0.1 nm to 0.9 nm, 0.1 nm to 0.8 nm, 0.1 nm to 0.7 nm, 0.1 nm to 0.6 nm, 0.1 nm to 0.5 nm, 0.1 nm to 0.4 nm, 0.1 nm to 0.3 nm, or 0.1 nm to 0.3 nm as measured by AFM.

In some embodiments, the polycrystalline diamond film has an Rₐ of 0.2 nm to 1 nm as measured by AFM. For example, in some embodiments, the polycrystalline diamond film has a Rₐ of 0.2 nm to 1 nm, or any range or subrange between 0.2 nm to 1 nm as measured by AFM. In some embodiments, the polycrystalline diamond film has a Rₐ of 0.2 nm to 0.9 nm, 0.3 nm to 0.8 nm, 0.4 nm to 0.7 nm, or 0.5 nm to 0.6 nm as measured by AFM. In some embodiments, the polycrystalline diamond film has a Rₐ of 0.3 nm to 1 nm, 0.4 nm to 1 nm, 0.5 nm to 1 nm, 0.6 nm to 1 nm, 0.7 nm to 1 nm, 0.8 nm to 1 nm, or 0.9 nm to 1 nm as measured by AFM. In some embodiments, the polycrystalline diamond film has a Rₐ of 0.2 nm to 0.8 nm, 0.2 nm to 0.7 nm, 0.2 nm to 0.6 nm, 0.2 nm to 0.5 nm, 0.2 nm to 0.4 nm, or 0.2 nm to 0.3 nm as measured by AFM.

In some embodiments, the polycrystalline diamond film has a root mean square surface roughness R_{q} of less than 1 nm as measured by AFM, as described herein.

In some embodiments, the polycrystalline diamond film has a thickness of 1 μm to 10 μm, or any range or subrange between 1 μm to 10 μm. For example, in some embodiments, the polycrystalline diamond film has a thickness of 2 μm to 9 μm, 3 μm to 8 μm, 4 μm to 7 μm, or 5 μm to 6 μm. In some embodiments, the polycrystalline diamond film has a thickness of 1 μm to 9 μm, 1 μm to 8 μm, 1 μm to 7 μm, 1 μm to 6 μm, 1 μm to 5 μm, 1 μm to 4 μm, 1 μm to 3 μm, or 1 μm to 2 μm.

In some embodiments, wherein the polycrystalline diamond film has a thickness that is less than a thickness of the polycrystalline substrate, as described herein.

In some embodiments, the polycrystalline substrate comprises a polycrystalline diamond. In some embodiments, the polycrystalline substrate comprises a plurality of diamond particles, as described herein.

In some embodiments, the polycrystalline substrate comprises a polycrystalline silicon carbide. In some embodiments, the polycrystalline substrate comprises a layer of silicon carbide.

In some embodiments, the polycrystalline substrate has a grain size that is measured within 5 μm of a layer of the polycrystalline substrate.

In some embodiments, the polycrystalline substrate has an average grain size of 4 μm to 100 μm, or any range or subrange between 4 μm to 100 μm. For example, in some embodiments, the polycrystalline substrate has an average grain size of 10 μm to 90 μm, 20 μm to 80 μm, 30 μm to 70 μm, or 40 μm to 60 μm. In some embodiments, the polycrystalline substrate has an average grain size of 10 μm to 100 μm, 20 μm to 100 μm, 30 μm to 100 μm, 40 μm to 100 μm, 50 μm to 100 μm, 60 μm to 100 μm, 70 μm to 100 μm, 80 μm to 100 μm, or 90 μm to 100 μm. In some embodiments, the polycrystalline substrate has an average grain size of 4 μm to 90 μm, 4 μm to 80 μm, 4 μm to 70 μm, 4 μm to 60 μm, 4 μm to 50 μm, 4 μm to 40 μm, 4 μm to 30 μm, 4 μm to 20 μm, 4 μm to 10 μm, or 4 μm to 5 μm.

In some embodiments, the polycrystalline substrate has an average grain size of 2 μm to 2000 μm, or any range or subrange between 2 μm to 2000 μm. For example, in some embodiments, the polycrystalline substrate has an average grain size of 5 μm to 1500 μm, 10 μm to 1000 μm, 50 μm to 500 μm, 100 μm to 400 μm, or 200 μm to 300 μm. In some embodiments, the polycrystalline substrate has an average grain size of 2 μm to 1500 μm, 2 μm to 1000 μm, 2 μm to 500 μm, 2 μm to 400 μm, 2 μm to 300 μm, 2 μm to 200 μm, 2 μm to 100 μm, 2 μm to 50 μm, 2 μm to 10 μm, or 2 μm to 5 μm. In some embodiments, the polycrystalline substrate has an average grain size of 5 μm to 2000 μm, 10 μm to 2000 μm, 50 μm to 2000 μm, 100 μm to 2000 μm, 500 μm to 2000 μm, 1000 μm to 2000 μm, or 1500 μm to 2000 μm.

In some embodiments, a polycrystalline substrate with a grain size greater than 2000 μm may comprise the single-crystalline material.

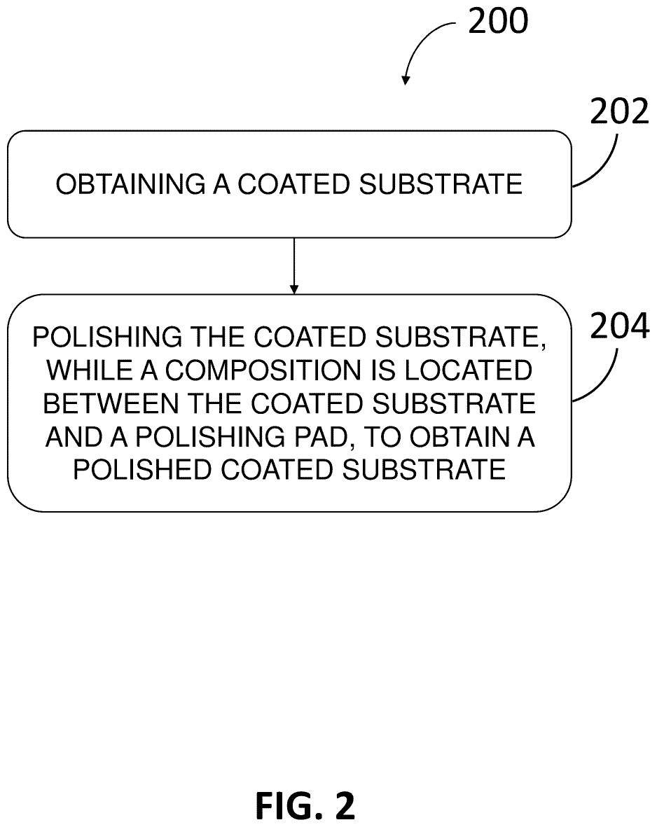

FIG. 2 is a flowchart of a method for obtaining a polished coated substrate, according to some embodiments. As shown in FIG. 2, the method for obtaining a polished coated substrate 200 may comprise one or more of the following steps: obtaining 202 a coated substrate, and polishing 204 the coated substrate, while a composition is located between the coated substrate and a polishing pad, to obtain a polished coated substrate.

At step 202, in some embodiments, the method comprises obtaining a coated substrate. In some embodiments, the coated substrate comprises a polycrystalline substrate, as described herein.

In some embodiments, the coated substrate comprises a polycrystalline diamond film located on the polycrystalline substrate. In some embodiments, the polycrystalline diamond film has an average grain size that is smaller than an average grain size of the polycrystalline substrate. In some embodiments, the polycrystalline diamond film has an average surface roughness Rₐ of 50 nm or less as measured by AFM. In some embodiments, the polycrystalline diamond film has a thickness of 1 μm to 10 μm, as described herein.

At step 204, in some embodiments, the method comprises polishing the coated substrate, while a composition is located between the coated substrate and a polishing pad, to obtain a polished coated substrate.

In some embodiments, the composition comprises a plurality of diamond particles having an average particle size of 5 nm to 100 μm or any range or subrange between 5 nm and 100 μm. In some embodiments, the plurality of diamond particles has an average particle size of 10 nm to 100 μm, 100 nm to 100 μm, 500 nm to 100 μm, 1 μm to 100 μm, 10 μm to 100 μm, 20 μm to 100 μm, 30 μm to 100 μm, 40 μm to 100 μm, 50 μm to 100 μm, 60 μm to 100 μm, 70 μm to 100 μm, 80 μm to 100 μm, or 90 μm to 100 μm. In some embodiments, the plurality of diamond particles has an average particle size of 5 nm to 90 μm, 5 nm to 80 μm, 5 nm to 70 μm, 5 nm to 60 μm, 5 nm to 40 μm, 5 nm to 30 μm, 5 nm to 20 μm, 5 nm to 10 μm, 5 nm to 1 μm, 5 nm to 500 nm, 5 nm to 100 nm, 5 nm to 50 nm, or 5 nm to 10 nm.

In some embodiments, the plurality of diamond particles is positioned on an outer surface of a soft-core particle comprising an inorganic material. In some embodiments, the soft-core particle comprises alumina, boron carbide, boron nitride, or silicon carbide. In some embodiments, the soft-core particle has an average size of at least 1 μm.

In some embodiments, the composition comprises an oxidizing agent on the plurality of particles. In some embodiments, the oxidizing agent is an isotropic oxidizer. Examples of isotropic oxidizer include per-compounds, e.g., permanganate, peroxides, perchlorates, perborates, periodates, etc. Examples of isotropic oxidizer also include peroxo-compounds e.g., peroxochromates, peroxomonosulfate, peroxodisulfate, etc.

In some embodiments, the composition comprises additives such as ions, alkali metals, pH modifiers, pH buffering agents, corrosion inhibitors, dispersants, anti-settling agents, or other additives.

In some embodiments, a pH of the composition is predetermined. In some embodiments, the composition has a pH of 1 to 13, or any range or subrange between 1 and 13. In some embodiments, for example, the composition has a pH of 2 to 12, 3 to 11, 4 to 10, 5 to 9, or 6 to 8. In some embodiments, the composition has a pH of 1 to 12, 1 to 11, 1 to 10, 1 to 9, 1 to 8, 1 to 7, 1 to 6, 1 to 5, 1 to 4, 1 to 3, or 1 to 2. In some embodiments, the composition has a pH of 2 to 13, 3 to 13, 4 to 13, 5 to 13, 6 to 13, 7 to 13, 8 to 13, 9 to 13, 10 to 13, 11 to 13, or 12 to 13.

In some embodiments, the composition has a pH of 9 to 15, or any range or subrange between 9 and 15. In some embodiments, the composition has a pH of 10 to 15, 11 to 15, 12 to 15, 13 to 15, or 14 to 15. In some embodiments, the composition has a pH of 9 to 14, 9 to 13, 9 to 12, 9 to 11, or 9 to 10.

In some embodiments, the composition has a pH of 0.1 to 5, or any range or subrange between 0.1 and 5. In some embodiments, the composition has a pH of 0.1 to 4, 0.1 to 3, 0.1 to 2, 0.1 to 1, or 0.1 to 0.5. In some embodiments, the composition has a pH of 0.5 to 5, 1 to 5, 2 to 5, 3 to 4, or 4 to 5.

Any composition known for chemical mechanical polishing (CMP) polishing may be used. In some embodiments, the composition is a proprietary composition from Entegris.

Any pad may be used for CMP polishing. The pad may be a soft pad or a hard pad. The pad may comprise a plurality of diamonds. In some embodiments, the pad is a proprietary from Entegris.

In some embodiments, the polishing comprises contacting the pad with the composition on the coated substrate. In some embodiments, the contacting comprises bringing the pad with the composition and the coated substrate into close or immediate proximity. In some embodiments, the contacting comprises bringing the pad with the composition and the coated substrate into direct physical contact. In some embodiments, the contacting comprises adding the composition to the pad, or vice versa. In some embodiments, the contacting comprises agitating the pad with the composition and the coated substrate. In some embodiments, the contacting comprises rotating the pad with the composition and the coated substrate. In some embodiments, the contacting comprises pouring the composition onto the pad. In some embodiments, the contacting comprises rubbing the pad with the composition on the coated substrate. In some embodiments, the contacting proceeds under conditions sufficient for removing at least a portion of a layer from the coated substrate. In some embodiments, the contacting comprises displacing at least a portion of a layer from the coated substrate. In some embodiments, the contacting comprises disassociating at least a portion of a layer from the coated substrate. In some embodiments, the contacting comprises breaking a bond located between at least a portion of a layer from the coated substrate. In some embodiments, the contacting comprises extracting at least a portion of a layer from the coated substrate. In some embodiments, the contacting comprises releasing at least a portion of a layer from the coated substrate.

In some embodiments, the contacting comprises rotating the coated substrate to contact the composition on a CMP apparatus. In some embodiments, the CMP apparatus further comprises the pad.

In some embodiments, the contacting comprises rotating the coated substrate to contact the composition at a platen rotation speed in a range of 25 RPM to 200 RPM, or any range or subrange between 25 RPM and 200 RPM. In some embodiments, the contacting comprises rotating the coated substrate to contact the composition at a platen rotation speed in a range of 50 RPM to 175 RPM, 75 RPM to 150 RPM, or 100 RPM to 125 RPM. In some embodiments, the contacting comprises rotating the coated substrate to contact the composition at a platen rotation speed in a range of 50 RPM to 200 RPM, 75 RPM to 200 RPM, 100 RPM to 200 RPM, 125 RPM to 200 RPM, 150 RPM to 200 RPM, or 175 RPM to 200 RPM. In some embodiments, the contacting comprises rotating the coated substrate to contact the composition at a platen rotation speed in a range of 25 RPM to 175 RPM, 25 RPM to 150 RPM, 25 RPM to 125 RPM, 25 RPM to 100 RPM, 25 RPM to 75 RPM, or 25 RPM to 50 RPM.

In some embodiments, the polished coated substrate has an average surface roughness Rₐ of less than 10 nm as measured by AFM.

For example, in some embodiments, the polished coated substrate has a Rₐ of 0.1 nm to 10 nm, or any range or subrange between 0.1 nm to 10 nm as measured by AFM. In some embodiments, the polished coated substrate has a Rₐ of 1 nm to 9 nm, 2 nm to 8 nm, 3 nm to 7 nm, or 4 nm to 6 nm as measured by AFM. In some embodiments, the polished coated substrate has a Rₐ of 0.1 nm to 9 nm, 0.1 nm to 8 nm, 0.1 nm to 7 nm, 0.1 nm to 6 nm, 0.1 nm to 5 nm, 0.1 nm to 4 nm, 0.1 nm to 3 nm, 0.1 nm to 2 nm, or 0.1 nm to 1 nm as measured by AFM. In some embodiments, the polished coated substrate has a Rₐ of 1 nm to 9 nm, 1 nm to 8 nm, 1 nm to 7 nm, 1 nm to 6 nm, 1 nm to 5 nm, 1 nm to 4 nm, 1 nm to 3 nm, or 1 nm to 2 nm as measured by AFM.

In some embodiments, the polished coated substrate has an Rₐ of 0.2 nm to 1 nm, or any range or subrange between 0.2 nm to 1 nm as measured by AFM. For example, in some embodiments, the polished coated substrate has a Rₐ of 0.2 nm to 0.9 nm, 0.3 nm to 0.8 nm, 0.4 nm to 0.7 nm, or 0.5 nm to 0.6 nm as measured by AFM. In some embodiments, the polished coated substrate has a Rₐ of 0.3 nm to 1 nm, 0.4 nm to 1 nm, 0.5 nm to 1 nm, 0.6 nm to 1 nm, 0.7 nm to 1 nm, 0.8 nm to 1 nm, or 0.9 nm to 1 nm as measured by AFM. In some embodiments, the polished coated substrate has a Rₐ of 0.2 nm to 0.8 nm, 0.2 nm to 0.7 nm, 0.2 nm to 0.6 nm, 0.2 nm to 0.5 nm, 0.2 nm to 0.4 nm, or 0.2 nm to 0.3 nm as measured by AFM.

Any one or more of the embodiments disclosed herein shall be understood to be combinable without departing from the scope or spirit of the disclosure.

### Example

A polycrystalline diamond film having an average grain size of 20 μm was deposited on a polycrystalline substrate via a chemical vapor deposition process. The average grain size of the polycrystalline diamond film was less than the average grain size of the polycrystalline substrate. The resulting coated substrate was then polished. Table 1 below summarizes the average surface roughness of the polycrystalline substrate without the polycrystalline film, and the average surface roughness of the polycrystalline diamond film after being deposited on the polycrystalline substrate and after being polished. All surface roughness measurements were obtained using an optical interferometer scan.

TABLE 1

| | Polycrystalline | Coated |
|---|---|---|
| | Substrate | Substrate |
| Average | 68.6 nm | 0.1 nm |
| Rₐ | 0.2 μm | 0.9 nm |
| Rₚ | 2.1 μm | 8.7 nm |
| R_{q} | 0.2 μm | 1.3 nm |
| Rₜ | 3.2 μm | 16.6 nm |
| Rᵥ | −1.1 μm | −7.9 nm |

As shown, by depositing the polycrystalline diamond film on the polycrystalline substrate and polishing the polycrystalline diamond film, the surface roughness of the coated substrate markedly improved relative to the polycrystalline substrate (i.e., without the polycrystalline diamond film).

### Aspects

Various Aspects are described below. It is to be understood that any one or more of the features recited in the following Aspect(s) can be combined with any one or more other Aspect(s).
Aspect 1. An article comprising:
   a polycrystalline substrate; and
   a polycrystalline diamond film located on the polycrystalline substrate,
      wherein the polycrystalline diamond film has an average grain size that is smaller than an average grain size of the polycrystalline substrate,
      wherein the polycrystalline diamond film has an average surface roughness Ra of 50 nm or less as measured by atomic force microscopy (AFM).
Aspect 2. The article according to Aspect 1, wherein the polycrystalline diamond film has an Ra of less than 1 nm as measured by AFM.
Aspect 3. The article according to any one of Aspects 1-2, wherein the polycrystalline diamond film has an Ra of 0.2 nm to 1 nm as measured by AFM.
Aspect 4. The article according to any one of Aspects 1-3, wherein the polycrystalline diamond film has an average grain size 10 times to 100 times smaller than an average grain size of the polycrystalline substrate.
Aspect 5. The article according to any one of Aspects 1-4, wherein the polycrystalline diamond film has a thickness that is less than a thickness of the polycrystalline substrate.
Aspect 6. The article according to any one of Aspects 1-5, wherein the polycrystalline diamond film has a thickness of 1 μm to 100 μm.
Aspect 7. The article according to any one of Aspects 1-6, wherein the polycrystalline diamond film has a thickness of 1 μm to 10 μm.
Aspect 8. The article according to any one of Aspects 1-7, wherein the polycrystalline diamond film has a root mean square surface roughness Rq of less than 1 nm as measured by AFM.
Aspect 9. The article according to any one of Aspects 1-8, wherein the polycrystalline substrate comprises at least one of a polycrystalline diamond, a diamond film stack, or any combination thereof.
Aspect 10. The article according to any one of Aspects 1-9, wherein the polycrystalline substrate comprises a polycrystalline silicon carbide.
Aspect 11. A method comprising:
   obtaining a gas mixture,
      wherein the gas mixture comprises a hydrogen and a hydrocarbon, and
   contacting a polycrystalline substrate with the gas mixture to form a polycrystalline diamond film on the polycrystalline substrate,
      wherein the polycrystalline diamond film has an average grain size that is smaller than an average grain size of the polycrystalline substrate,
      wherein the polycrystalline diamond film has an average surface roughness Ra of 50 nm or less as measured by atomic force microscopy (AFM).
Aspect 12. The method according to Aspect 11, wherein the polycrystalline substrate comprises at least one of a polycrystalline diamond, a diamond film stack, or any combination thereof.
Aspect 13. The method according to any one of Aspects 11-12, wherein the polycrystalline substrate comprises a polycrystalline silicon carbide.
Aspect 14. The method according to any one of Aspects 11-13, wherein the polycrystalline diamond film has an Ra of 0.2 nm to 1 nm as measured by AFM.
Aspect 15. The method according to any one of Aspects 11-14, wherein the polycrystalline diamond film has a thickness of 1 μm to 10 μm.
Aspect 16. The method according to any one of Aspects 11-15, wherein the polycrystalline diamond film has a thickness that is less than a thickness of the polycrystalline substrate.
Aspect 17. The method according to any one of Aspects 11-16, wherein the polycrystalline diamond film has a root mean square surface roughness Rq of less than 1 nm as measured by AFM.
Aspect 18. A method:

obtaining an article,
wherein the article comprises a coated substrate,
wherein the coated substrate comprises:
a polycrystalline substrate; and
a polycrystalline diamond film located on the
polycrystalline substrate,
wherein the polycrystalline diamond film has an
average grain size that is smaller than an
average grain size of the polycrystalline
substrate,
wherein the polycrystalline diamond film has an
average surface roughness Rₐ of 50 nm or less
as measured by atomic force microscopy
(AFM); and

polishing the coated substrate, while a composition is located between the coated substrate and a polishing pad, to obtain a polished coated substrate,
   wherein the polished coated substrate has an average surface roughness Rₐ of less than 10 nm as measured by AFM.
Aspect 19. The method according to Aspect 18, wherein the polycrystalline diamond film has a thickness of 1 μm to 10 μm.
Aspect 20. The method according to any one of Aspects 18-19, wherein the polished coated substrate has an Ra of 0.2 nm to 1 nm as measured by AFM.

What is claimed is:

1. An article comprising:
a polycrystalline substrate; and
a polycrystalline diamond film located on the polycrystalline substrate,
wherein the polycrystalline diamond film has an average grain size that is smaller than an average grain size of the polycrystalline substrate,
wherein the polycrystalline diamond film has an average surface roughness Rₐ of 50 nm or less as measured by atomic force microscopy (AFM).

2. The article of claim 1, wherein the polycrystalline diamond film has an Rₐ of less than 1 nm as measured by AFM.

3. The article of claim 1, wherein the polycrystalline diamond film has an Rₐ of 0.2 nm to 1 nm as measured by AFM.

4. The article of claim 1, wherein the polycrystalline diamond film has an average grain size 10 times to 100 times smaller than an average grain size of the polycrystalline substrate.

5. The article of claim 1, wherein the polycrystalline diamond film has a thickness that is less than a thickness of the polycrystalline substrate.

6. The article of claim 1, wherein the polycrystalline diamond film has a thickness of 1 μm to 100 μm.

7. The article of claim 1, wherein the polycrystalline diamond film has a thickness of 1 μm to 10 μm.

8. The article of claim 1, wherein the polycrystalline diamond film has a root mean square surface roughness R_{q} of less than 1 nm as measured by AFM.

9. The article of claim 1, wherein the polycrystalline substrate comprises at least one of a polycrystalline diamond, a diamond film stack, or any combination thereof.

10. The article of claim 1, wherein the polycrystalline substrate comprises a polycrystalline silicon carbide.

11. A method comprising:
obtaining a gas mixture,
wherein the gas mixture comprises a hydrogen and a hydrocarbon; and
contacting a polycrystalline substrate with the gas mixture to form a polycrystalline diamond film on the polycrystalline substrate,
wherein the polycrystalline diamond film has an average grain size that is smaller than an average grain size of the polycrystalline substrate,
wherein the polycrystalline diamond film has an average surface roughness Rₐ of 50 nm or less as measured by atomic force microscopy (AFM).

12. The method of claim 11, wherein the polycrystalline substrate comprises at least one of a polycrystalline diamond, a diamond film stack, or any combination thereof.

13. The method of claim 11, wherein the polycrystalline substrate comprises a polycrystalline silicon carbide.

14. The method of claim 11, wherein the polycrystalline diamond film has an Rₐ of 0.2 nm to 1 nm as measured by AFM.

15. The method of claim 11, wherein the polycrystalline diamond film has a thickness of 1 μm to 10 μm.

16. The method of claim 11, wherein the polycrystalline diamond film has a thickness that is less than a thickness of the polycrystalline substrate.

17. The method of claim 11, wherein the polycrystalline diamond film has a root mean square surface roughness R_{q} of less than 1 nm as measured by AFM.

18. A method:
obtaining an article,
wherein the article comprises a coated substrate,
wherein the coated substrate comprises:
a polycrystalline substrate; and
a polycrystalline diamond film located on the polycrystalline substrate,
wherein the polycrystalline diamond film has an average grain size that is smaller than an average grain size of the polycrystalline substrate,
wherein the polycrystalline diamond film has an average surface roughness Rₐ of 50 nm or less as measured by atomic force microscopy (AFM); and
polishing the coated substrate, while a composition is located between the coated substrate and a polishing pad, to obtain a polished coated substrate,
wherein the polished coated substrate has an average surface roughness Rₐ of less than 10 nm as measured by AFM.

19. The method of claim 18, wherein the polycrystalline diamond film has a thickness of 1 μm to 10 μm.

20. The method of claim 18, wherein the polished coated substrate has an Rₐ of 0.2 nm to 1 nm as measured by AFM.
